(19) United States
(12) Patent Application Publication
(10) Pub. No.: US 2002/0086483 A1
(43) Pub. Date: Jul. 4, 2002

(54) Fabrication method of single electron tunneling transistors using a focused-ion beam

(75) Inventors: Eun Kyu Kim, Seoul (KR); Young Ju Park, Seoul (KR); Tae Whan Kim, Seoul (KR); Seung Oun Kang, Seoul (KR); Dong Chul Choo, Uijeongbu-shi (KR); Jae Hwan Shim, Seoul (KR)

Correspondence Address: OLIFF & BERRIDGE, PLC, P.O. BOX 19928, ALEXANDRIA, VA, 22320, US

(73) Assignee: KOREA INSTITUTE OF SCIENCE AND TECHNOLOGY, Seoul (KR)

(21) Appl. No.: 10/026,879

(22) Filed: Dec. 27, 2001

(30) Foreign Application Priority Data
Dec. 29, 2000 (KR) 2000-85534

(51) Int. Cl. H01L 21/336

(52) U.S. Cl. 438/264

(57) ABSTRACT

Disclosed is a method for fabricating a single electron tunneling transistor. In the above method, an insulating layer and a conductive layer are orderly formed on a substrate. The conductive layer is patterned such that the insulating layer is exposed, to form a T-shaped conductive pattern of which a first portion arranged in a vertical direction is connected to a middle portion of a second portion arranged in a horizontal direction. A focused-ion beam is irradiated onto the connected middle portion of the T-shaped conductive pattern such that the second portion is cut at a middle portion thereof and the first portion is separated from the first portion, to form nano-crystal regions respectively at a first cut portion of the first pattern and a second cut portion of the second pattern using an irradiation effect of the focused-ion beam. A first nano-crystal region positioned at the first cut portion of the first pattern becomes a single electron tunnel junction and a second nano-crystal region positioned at the second cut portion of the second pattern becomes a capacitive junction. By the above method, it becomes possible to fabricate a tunneling transistor capable of easily overcoming the single electron tunneling blockade effect at room temperature by thermal oscillation phenomenon and quantum interference phenomenon.

### BACKGROUND OF THE INVENTION

1. Field of the Invention

The present invention relates to a fabrication method of a single electron tunneling transistor, and more particularly, to a fabrication method of a single electron tunneling transistor operated at the room temperature utilizing a focused-ion beam.

2. Description of the Related Art

As manufacturing technologies of semiconductor devices are developed, sizes of semiconductor devices have correspondingly shrunk. In the long run, there has emerged a single electron tunneling transistor capable of performing a signal transmission operation by providing a repeatable and measurable response to the presence or absence of a single electron. The single electron tunneling transistor is one of the most promising candidates for next generation ultra high density memory device with a memory capacitance of tera byte level or more. In order for nucleus to have the binding force greater than the thermal fluctuation energy of electrons at room temperature, the crystal size for the binding of electrons should be a few ten nm or less.

In case of the single electron tunneling transistor, it is necessary to control a tunnel current generated by a single electron tunneling between the source and the drain using the gate voltage. Accordingly, a tunnel junction should exist between the source and the drain, and a capacitive junction in which the tunnel current is not generated between the source-drain tunnel junction and the gate should exist too.

At the present, there are disclosed various experimental approaches, for instance, a method using a quantum dot, an electron beam lithography method, a method for forming polycrystalline silicon, etc. However, there are several problems in applying these methods to a real process because of a complicated process.

In spite of these circumstances, there is not yet any try to fabricate a single electron transistor using a focused-ion beam processing technology in which a technical development reaches a level capable of directly processing an ultra fine structure of a unit of micron (μm) or less based on the development of liquid metal ion source.

### SUMMARY OF THE INVENTION

Therefore, it is an object of the present invention to provide a method for fabricating a single electron tunneling transistor capable of operating at room temperature using a focused-ion beam.

To accomplish the above object and other advantages, there is provided a method for fabricating a single electron tunneling transistor. In the above method, an insulating layer and a conductive layer are orderly formed on a substrate. The conductive layer is patterned such that the insulating layer is exposed, to form a T-shaped conductive pattern of which a first portion arranged in a vertical direction is connected to a middle portion of a second portion arranged in a horizontal direction. A focused-ion beam is irradiated onto the connected middle portion of the T-shaped conductive pattern such that the second portion is cut at a middle portion thereof and the first portion is separated from the first portion, to form nano-crystal regions respectively at a first cut portion of the first pattern and a second cut portion of the second pattern using an irradiation effect of the focused-ion beam. A first nano-crystal region positioned at the first cut portion of the first pattern becomes a single electron tunnel junction and a second nano-crystal region positioned at the second cut portion of the second pattern becomes a capacitive junction.

### BRIEF DESCRIPTION OF THE DRAWINGS

The above objects and other advantages of the present invention will become more apparent by describing preferred embodiments thereof in detail with reference to the attached drawings in which:

FIGS. 1A to 1E are schematic views and photographs for describing a fabrication method of a single electron transistor in the same planar gate type in accordance with one preferred embodiment of the present invention;

FIGS. 2A and 2B are schematic views for describing radiation effect of a focused-ion beam; and

FIG. 3 is a graph showing a variation in the source-drain current when the gate voltage is varied after the source-drain voltage is fixed around a threshold voltage.

### DETAILED DESCRIPTION OF THE PREFERRED EMBODIMENTS

Hereinafter, preferred embodiments of the present invention will be described in detail with reference to the accompanying drawings.

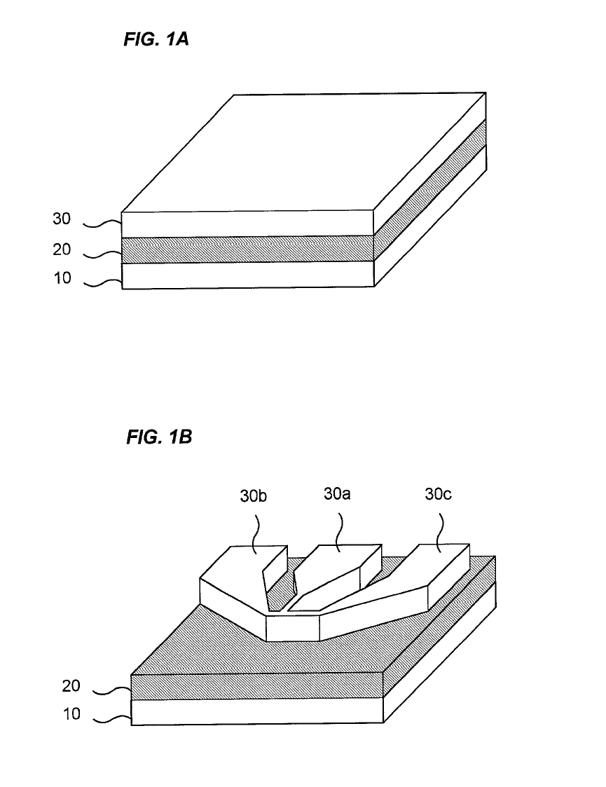

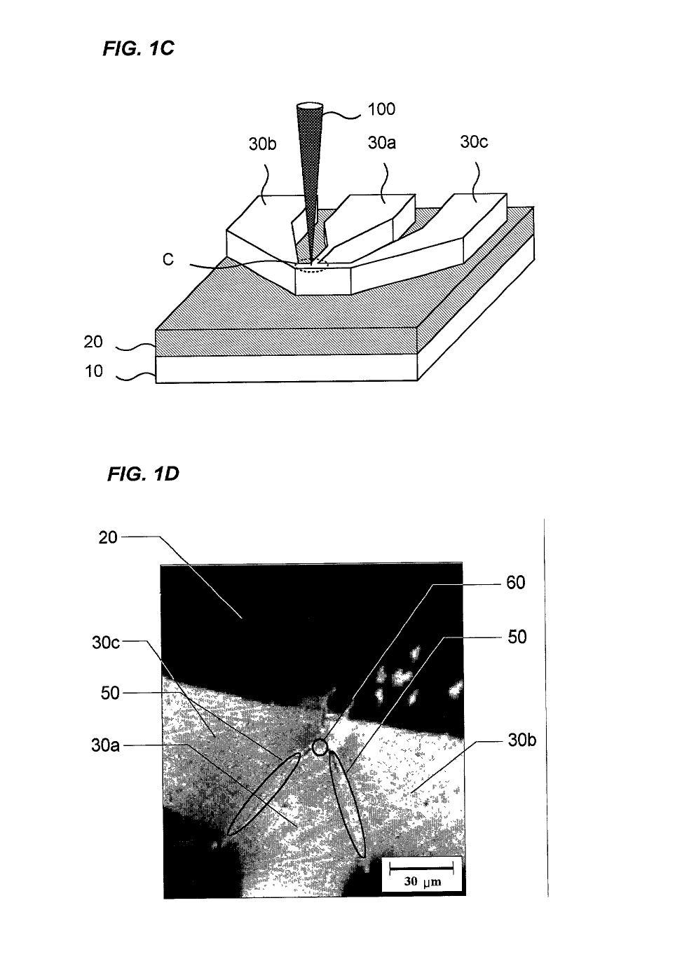

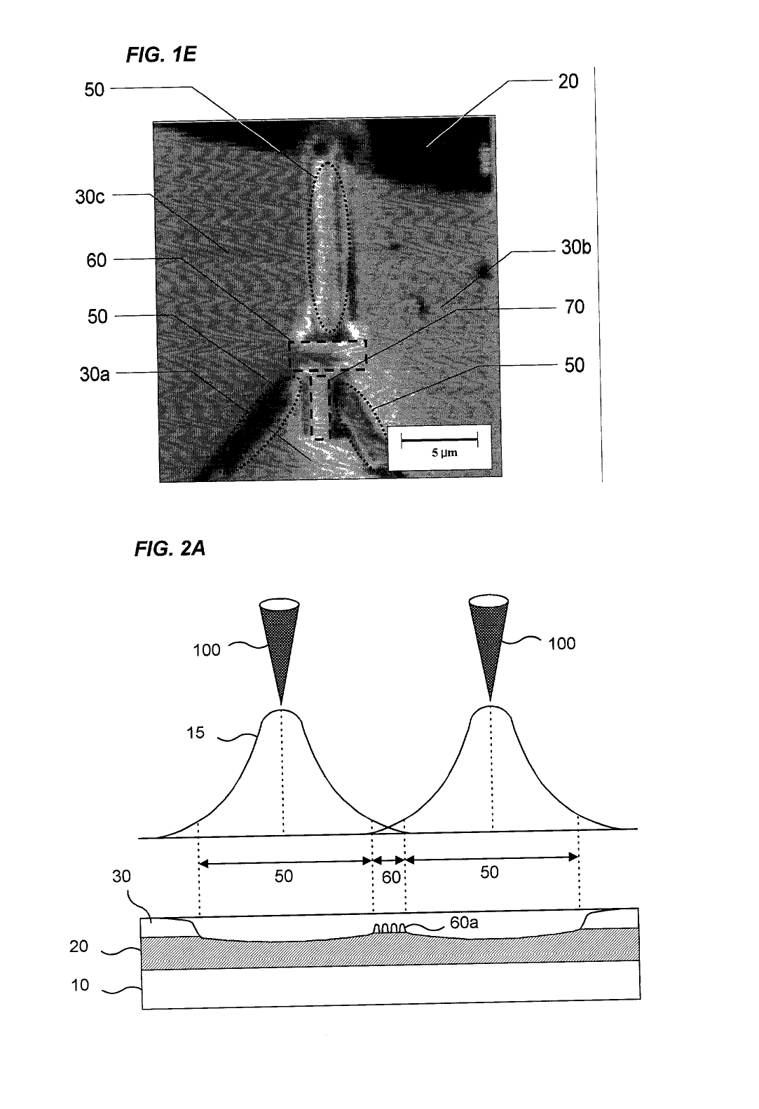

FIG. 1A to FIG. 1E are schematic views and photographs for describing a same plane gate type single electron transistor.

First, an insulating layer 20 and a conductive layer 30 are formed on a substrate 10 in the order named. For instance, an MgO layer having a thickness ranged from 2,000 Å to 3,000 Å and an Al layer having a thickness of approximately 1,000 Å are stacked on a p-type silicon substrate in the order named. Alternatively, dopants-doped polycrystalline silicon can be used instead of the aforementioned Al layer as the conductive layer 30.

After that, the conductive layer 30 is patterned using a photolithography process such that the insulating layer 20 is exposed, and thereby a T-shaped conductive pattern is formed, of which a first portion arranged in a vertical direction is connected to a middle portion of a second portion arranged in a horizontal direction. Both side portions of the first portion correspond to a source electrode 30b and a drain electrode 30c, respectively, and the second portion corresponds to a gate electrode 30c.

Thereafter, a focused-ion beam, for instance, Ga⁺-focused ion beam, is irradiated onto the connected portion of the T-shaped conductive pattern to form a single electron tunnel junction 60 and a capacitive junction 70. Preferably, the irradiation process of the Ga⁺-focused ion beam is carried out under a condition of an acceleration voltage of approximately 15 kV and a beam current of approximately 90 pA.

After the irradiation process is carried out, a resultant substrate is directly observed using a transmission electron microscope (TEM) of high power and its photograph is shown in FIG. 1D. FIG. 1E is a photograph enlarged to a higher power than FIG. 1D.

Referring to FIGS. 1D and 1E, the focused-ion beam should be irradiated such that a completely removed region 50 in the T-shaped conductive pattern appears. In other words, the focused-ion beam should be irradiated such that the second portion is cut at a middle portion thereof and the first portion is separated from the first portion. To this end, a source electrode 30b, a drain electrode 30c and a gate electrode 30a are separated from each other.

At this time, it is necessary to form the single electron tunnel junction 60 by a radiation effect of the focused-ion beam between the source electrode 30b and the drain electrode 30c and to form the capacitive junction 70 between the single electron tunnel junction 60 and the gate electrode 30a.

Each of the single electron tunnel junction 60 and the capacitive junction includes a nano-crystal region formed by the radiation effect of the focused-ion beam. However, there is a difference between them in that the single electron tunnel junction 60 is higher in the density of the nano-crystal than the capacitive junction 70. The less the density of the nano-crystal is, the less a tunneling probability is, so that tunneling occurs more frequently in the single electron tunnel junction 60 than in the capacitive junction 70.

The aforementioned terms of “single electron tunnel junction 60” and “capacitive junction 70” are functional names. In other words, they are named from a fact that under a certain voltage, the tunneling occurs at the single electron tunnel junction while it does not occur at the capacitive junction 70.

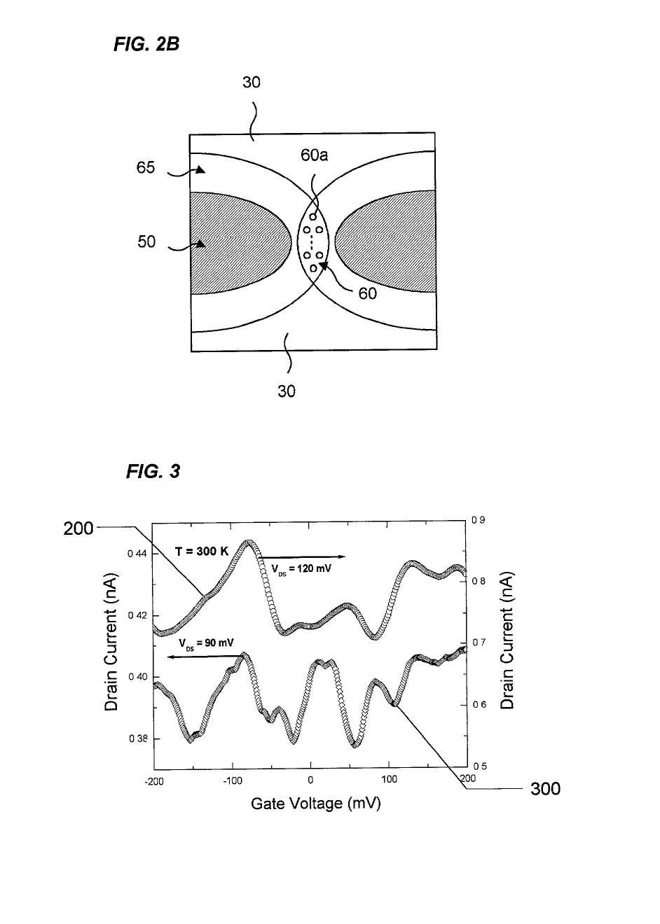

FIGS. 2A and 2B are schematic views for describing a radiation effect of a focused-ion beam. Specifically, FIG. 2A is a sectional view and FIG. 2B is a plan view.

Referring to FIGS. 2A and 2B, energy density of a focused-ion beam has a Gaussian distribution with reference to focuses as indicate by a numeric of 15. Thus, if a focused-ion beam is irradiated onto a surface of the conductive layer 30 through a probe 100, the conductive layer 30 are completely removed at a focal portion on which the ion beam is focused in the conductive layer 30, whereby a completely removed region 50 is formed, while the conductive layer 30 is not completely removed but is partially removed in the vicinity of the focal portion, whereby a partially removed region 65 appears.

At the partially removed region 65 of the conductive layer 30 are partially broken atomic bonds due to the radiation effect of the focused-ion beam, so that partial defects are generated. These defects vary with the energy density of the focused-ion beam that is implanted into the conductive layer 30 as a workpiece, the focused degree, the irradiation time, etc. Especially, this phenomenon occurs more frequently at an overlapped portion of the focused-ion beams. Therefore, if the implantation of the focused-ion beams are carried out in some degree, a nano-crystal region that is a group region of nano-crystals 60a is formed due to a bond breaking in atomic structure. This nano-crystal region becomes the single electron tunnel junction 60.

If the irradiation time further elapses, even the nano-crystal 60a is etched away, so that the density of the nano-crystal grows less and less. To this end, such a tunneling does not occur with ease, so that the nano-crystal region becomes the capacitive junction 70.

Again referring to FIG. 1E, it is known that the capacitive junction 70 is less in width than the single electron tunnel junction 60. This is because the capacitive junction 70 is exposed to the focused-ion bema much larger than the single electron tunnel junction 60 and thereby the nano-crystals disappear. Practically, the single electron tunnel junction 60 that is operable at room temperature has a width of approximately 2 μm and the capacitive junction 70 has a width of approximately 1 μm.

Crystallization of nano-crystals 60a is carried out by a secondary electron generated by an impact between the ions of the focused ion beam and atoms of the workpiece or other factor.

FIG. 3 is a graph showing a variation in the source-drain current when the gate voltage is varied after the source-drain voltage is fixed around a threshold voltage. In FIG. 3, a numeral 200 indicates that the source-drain voltage is 120 mV and a numeral 300 indicates that the source-drain voltage is 90 mV.

Referring to FIG. 3, there is shown a phenomenon that the source-drain current oscillates at several positions. This is due to coulomb blockade phenomenon and is a result indirectly showing that a few ten nm or less-sized nano-crystal was formed in the single electron tunnel junction 60.

From the result of FIG. 3, the oscillation in the source-drain current, i.e., the coulomb oscillation has a period of approximately 145 mV and a coulomb blockade voltage of approximately 80 mV.

Based on the above values, equivalent static capacitances of the single electron tunnel junction 60 and the capacitive junction 70 were computed and thereby two values of 2×10⁻¹⁹ F. that is the equivalent static capacitance of the single electron tunnel junction 60 and 1.1×10⁻¹⁹ F. that is the equivalent static capacitance of the capacitive junction 70 were obtained.

As described previously, the fabrication method of the single electron tunnel transistor in accordance with the present invention allows a few nm or less-sized nano-crystals to be formed with ease and simplicity using the focused-ion beam, in which the single electron tunnel junction region 60 and the capacitive junction region 70 are formed at the same time by controlling the radiation effect depending on an exposure time and amount of the focused-ion beam. As a result, it becomes possible to fabricate a tunneling transistor capable of easily overcoming the single electron tunneling blockade effect at room temperature by thermal oscillation phenomenon and quantum interference phenomenon.

While the present invention has been described in detail, it should be understood that various changes, substitutions and alterations can be made hereto without departing from the spirit and scope of the invention as defined by the appended claims.

What is claimed is:

1. A method for fabricating a single electron tunneling transistor, the method comprising the steps of:
orderly forming an insulating layer and a conductive layer on a substrate;
patterning the conductive layer such that the insulating layer is exposed, to form a T-shaped conductive pattern of which a first portion arranged in a vertical direction is connected to a middle portion of a second portion arranged in a horizontal direction; and
irradiating a focused-ion beam onto the connected middle portion of the T-shaped conductive pattern such that the second portion is cut at a middle portion thereof and the first portion is separated from the first portion, to form nano-crystal regions respectively at a first cut portion of the first pattern and a second cut portion of the second pattern using an irradiation effect of the focused-ion beam, wherein a first nano-crystal region positioned at the first cut portion of the first pattern becomes a single electron tunnel junction and a second nano-crystal region positioned at the second cut portion of the second pattern becomes a capacitive junction.

2. The method of claim 1, wherein the substrate is a p-type silicon substrate.

3. The method of claim 1, wherein the insulating layer is comprised of MgO 2,000-3,000 Å thick.

4. The method of claim 1, wherein the conductive layer is comprised of Al 800-1,200 Å thick.

5. The method of claim 1, wherein the conductive layer is comprised of impurity-doped polycrystalline silicon 800-1,200 Å thick.

6. The method of claim 1, wherein the focused-ion beam is comprised of Ga⁺-focused ion beam.

7. The method of claim 1, the Ga⁺-focused ion beam is irradiated under a condition of an acceleration voltage of 10-20 kV and a beam current of 70-110 pA.

8. The method of claim 1, wherein the single electron tunnel junction has a width of 1.8-2.2 μm and the capacitive junction has a width of 0.8-1.2 μm.
